(19) United States
(12) Patent Application Publication
(10) Pub. No.: US 2015/0255637 A1
(43) Pub. Date: Sep. 10, 2015

(54) PHOTOVOLTAIC DEVICES INCORPORATING THIN CHALCOGENIDE FILM ELECTRICALLY INTERPOSED BETWEEN PNICTIDE-CONTAINING ABSORBER LAYER AND EMITTER LAYER

(71) Applicants: DOW GLOBAL TECHNOLOGIES LLC, Midland,, MI (US); CALIFORNIA INSTITUTE OF TECHNOLOGY, Pasadena, CA (US)

(72) Inventors: Jeffrey P. Bosco, Los Angeles, CA (US); Rebekah K. Feist, Midland, MI (US); Harry A. Atwater, South Pasadena, CA (US); Marty W. Degroot, Middletown, DE (US); James C. Stevens, Richmond, TX (US); Gregory M. Kimball, Campbell, CA (US)

(21) Appl. No.: 14/433,221

(22) PCT Filed: Oct. 7, 2013
(86) PCT No.: PCT/US2013/063705

§ 371 Date: Apr. 2, 2015

Related U.S. Application Data
(60) Provisional application No. 61/711,580, filed on Oct. 9, 2012.

(51) Int. Cl. H01L 31/0296; H01L 31/032; H01L 31/18; H01L 31/072

(52) U.S. Cl. CPC H01L 31/0296; H01L 31/072; H01L 31/032; H01L 31/1828

(57) ABSTRACT

The present invention provides strategies for improving the quality of the insulating layer in MIS and SIS devices in which the insulator layer interfaces with at least one pnictide-containing film The principles of the present invention are based at least in part on the discovery that very thin (20 nm or less) insulating films comprising a chalcogenide such as i-ZnS are surprisingly superior tunnel barriers in MIS and SIS devices incorporating pnictide semiconductors. In one aspect, the present invention relates to a photovoltaic device, comprising: a semiconductor region comprising at least one pnictide semiconductor; an insulating region electrically coupled to the semiconductor region, wherein the insulating region comprises at least one chalcogenide and has a thickness in the range from 0.5 nm to 20 nm; and a rectifying region electrically coupled to the semiconductor region in a manner such that the insulating region is electrically interposed between the collector region and the semiconductor region.

### PRIORITY CLAIM

The present patent application claims the benefit of U.S. Provisional patent application Ser. No. 61/711,580 filed on Oct. 9, 2012, and entitled “PHOTOVOLTAIC DEVICES INCORPORATING THIN CHALCOGENIDE FILM ELECTRICALLY INTERPOSED BETWEEN PNICTIDE-CONTAINING ABSORBER LAYER AND EMITTER LAYER,” wherein the entirety of said provisional patent application is incorporated herein for all purposes.

### TECHNICAL FIELD

The present invention is in the field of photovoltaic devices of the type having absorber-insulator-collector structures (e.g., MIS and SIS structures). More particularly, the present invention relates to such devices in which the insulator is an ultrathin layer comprising at least one chalcogenide and at least one semiconductor layer comprises a pnictide semiconductor.

### BACKGROUND ART

Pnictide-based semiconductors include the Group IIB/VA semiconductors. Zinc phosphide (Zn₃P₂) is one kind of Group IIB/VA semiconductor. Zinc phosphide and similar pnictide-based semiconductor materials have significant potential as photoactive absorbers in thin film photovoltaic devices. Zinc phosphide, for example, has a reported direct band gap of 1.5 eV, high light absorbance in the visible region (e.g., greater than 10⁴ to 10⁵ cm⁻¹), and long minority carrier diffusion lengths (about 5 to about 10 μm). N. C. Wyeth and A. Catalano, Journal of Applied Physics 50 (3), 1403-1407 (1979). This would permit high current collection efficiency. Also, materials such as Zn and P are abundant and low cost.

Zinc phosphide is known to be either p-type or n-type. To date, it has been much easier to fabricate p-type zinc phosphide. See A. Catalano and R. B. Hall, Journal of Physics and Chemistry of Solids 41 (6), 635-640 (1980). Preparing n-type zinc phosphide, particularly using methodologies suitable for the industrial scale, remains challenging. Investigators have prepared n-type zinc phosphide using molecular beam epitaxy techniques using separate zinc and phosphide sources. Suda et al. Applied Physics Letters, 69(16), 2426 (1996). These films did not exhibit photovoltaic behavior due to poor film quality and lack of control over stoichiometry. This has confounded the fabrication of p-n homojunctions based upon zinc phosphide.

Consequently, solar cells using zinc phosphide most commonly are constructed with Mg Schottky contacts, liquid contacts, or pin heterojunctions. F. C. Wang, A. L. Fahrenbruch and R. H. Bube, Journal of Applied Physics 53 (12), 8874-8879 (1982). M. Bhushan, J. A. Turner and B. A. Parkinson, Journal of the Electrochemical Society 133 (3), 536-539 (1986). M. Bhushan and A. Catalano, Applied Physics Letters 38 (1), 39-41 (1981). Exemplary photovoltaic devices include those incorporating Schottky contacts based upon p-Zn₃P₂/Mg and have exhibited greater than about 6% efficiency for solar energy conversion. M. Bhushan and A. Catalano, Applied Physics Letters 38 (1), 39-41 (1981). The efficiency of such diodes theoretically limits open circuit voltage to about 0.5 volts due to the about 0.8 eV barrier height obtained for junctions comprising Zn₃P₂ and metals such as Mg.

Schottky type devices based on zinc phosphide and metal contacts such as Mg have been limited in performance. As one factor, controlling the quality of the metal-semiconductor interface has been difficult. One approach to improving the performance of these devices is to incorporate an insulating layer, or tunnel barrier, at the interface between the semiconductor and metal. Such a structure is known as a metal-insulator-semiconductor (MIS) device. MIS devices generally demonstrate better performance than conventional Schottky devices due at least in part to lower interface trap density. In electronics, a tunnel barrier, also referred to as a tunnel junction, is a barrier, such as a thin insulating layer or electric potential, between two materials that relatively are more electrically conducting than the tunnel barrier. Without wishing to be bound by theory, electric current is believed to pass through the barrier by the process of quantum tunneling. Classically, the electron current has zero probability of passing through the barrier. However, according to quantum mechanics, the electron has a non-zero wave amplitude in the barrier, and hence it has some probability of passing through the barrier. In actual practice, electric current in fact passes through the barrier.

Previous MIS devices based on zinc phosphide were fabricated using a relatively thick, Al₂O₃ insulating layer and an Al top contact. M. S. Casey, A. L. Fahrenbruch, R. H. Bube, J. Appl. Phys. 61 (1987) 2941-2946. These devices were fabricated to investigate surface properties of zinc phosphide through capacitance-voltage measurements, not to optimize photovoltaic response.

SIS devices are similar in structure to MIS devices except that the insulating layer is sandwiched between two semiconductor layers in an SIS device. Theoretically, one of the S layers can be viewed as providing an absorbing function while the other S layer can be viewed as providing a collector function. Desirably, the interface between the insulating layer and one or both of the semiconductor layers is higher quality in some instances than would be the interface between two semiconductors in the absence of the insulating layer.

Much research and development effort is focused upon improving the electronic performance of MIS and SIS devices, particularly photovoltaic devices that incorporate pnictide-based semiconductors. In particular, strategies for improving the quality of the insulating layer and its interface(s) with the other layers are needed.

### SUMMARY OF THE INVENTION

The present invention provides strategies for improving the quality of the insulating layer in MIS and SIS devices in which the insulator layer interfaces with at least one pnictide-containing film. The principles of the present invention are based at least in part on the discovery that very thin (20 nm or less) insulating films comprising a chalcogenide (such as i-ZnS) are surprisingly superior tunnel barriers in MIS and SIS devices incorporating pnictide semiconductors. The discovery is unexpected at least in part due to the conventional understanding that the interface between pnictide semiconductors (such as p-type Zn₃P₂)and semiconductor chalcogenides (such as relatively thick, e.g., 80 nm or more, n-type ZnS) tends to have poor electronic qualities for purposes of forming p-n heterojunctions. It is surprising, therefore, that an interface between p-type Zn₃P₂ and intrinsic ZnS would perform so well electronically in MIS and SIS structures when the interface energetics between p-type Zn₃P₂ and ZnS is associated with poor performance in the context of p-n structures. The present invention appreciates that electronic properties such as the conduction and valence band offsets associated with pnictide semiconductors and chalcogenide materials might be unsuitable for p-n structures but nonetheless are very well matched for use in MIS or SIS structures.

In one aspect, the present invention relates to a photovoltaic device, comprising:

a) a semiconductor region comprising at least one pnictide semiconductor;
b) an insulating region electrically coupled to the semiconductor region, wherein the insulating region comprises at least one chalcogenide and has a thickness in the range from 0.5 nm to 20 nm; and
c) a rectifying region in rectifying, electrical communication with the semiconductor region in a manner such that the insulating region is electrically interposed between the collector region and the semiconductor region.

In another aspect, the present invention relates to a method of making a photovoltaic device, comprising the steps of:

a) providing a semiconductor layer comprising at least one pnictide semiconductor;
b) forming an insulating layer directly or indirectly on the semiconductor layer, wherein the insulating layer comprises at least one chalcogenide and has a thickness in the range from 0.5 nm to 20 nm; and
c) forming an additional layer directly or indirectly on the insulating layer such that the insulating layer is interposed between the additional layer and the semiconductor layer and such that the semiconductor layer, the insulating layer, and the additional layer form a photovoltaic junction in which the additional layer is in rectifying electrical communication with the semiconductor layer.

### BRIEF DESCRIPTION OF THE DRAWINGS

FIG. 1 is a schematic illustration in cross-section of an illustrative photovoltaic device incorporating a pnictide semiconductor.

FIG. 2 is a graph showing a possible bandgap alignment for a heterojunction between p-type zinc phosphide and n-type zinc sulfide, wherein the large conduction band spike for the interface indicates an unfavorable heterojunction.

FIG. 3a schematically illustrates a Mg/i-ZnS/p-Zn3P2 MIS photovoltaic device of the present invention.

FIG. 3b shows current-voltage measurements under dark and AM1.5 1-Sun illumination for the Mg/i-ZnS/p-Zn3P2 MIS photovoltaic device of FIG. 3a.

FIG. 4a schematically shows a n-ZnS/p-Zn3P2 heterojunction photovoltaic device.

FIG. 4b shows current-voltage measurements under dark and AM1.5 1-Sun illumination for the n-ZnS/p-Zn3P2 heterojunction photovoltaic device of FIG. 4a.

FIG. 5 schematically illustrates Type I, II and III band gap alignments for a p-n heterojunction.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited herein are incorporated herein by reference in their respective entireties for all purposes.

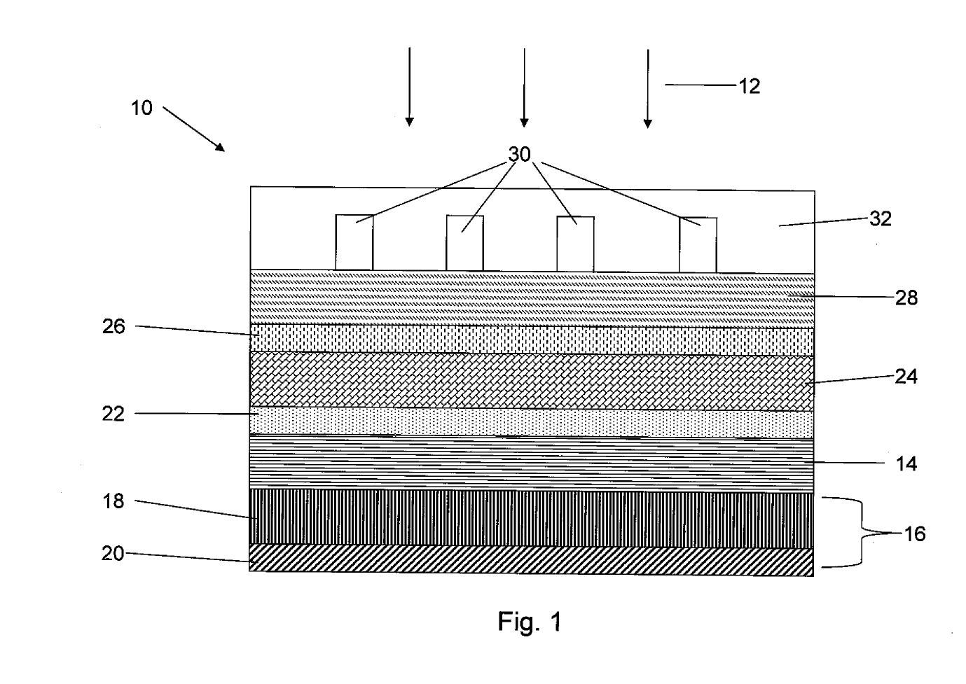

The principles of the present invention are used to provide photovoltaic devices incorporating thin chalcogenide film(s) that are electrically interposed between pnictide-containing absorber layers and emitter layers. The photovoltaic devices demonstrate improved electronic performance. FIG. 1 schematically shows an illustrative embodiment of a photovoltaic device 10 according to the present invention. Device 10 incorporates photovoltaic functionality so that incident light 12 is converted into electrical energy.

Device 10 incorporates semiconductor region 14. Without wishing to be bound by theory, it is believed that the semiconductor region 14 functions at least in part as an absorber region (also referred to as an absorber-generator). In the context of a photovoltaic device, an absorber refers to a medium that absorbs photons (i.e., incident light) and generates a photocurrent. It is believed that the photocurrent results from the generation of electron-hole pairs. Negatively charged electrons are the minority carriers in a p-type semiconductor region. Positively charged carriers (“holes”) are the minority carriers in an n-type semiconductor region. Preferred semiconductor regions of the present invention are p-type. With this theory in mind, semiconductor region 14 desirably incorporates at least one semiconductor material having a band gap for capturing light (e.g., 1.3 to 1.6 eV), a high absorption coefficient for capturing incident light (e.g. α>1×10⁴ cm⁻¹), and long minority carrier diffusion length (e.g., >5 μm). The semiconductor material desirably has an intermediate resistivity, e.g., a resistivity in the range from about 1×10⁻² ohm-cm to about 1×10² ohm-cm. Zinc phosphide is an example of a semiconductor material having such characteristics.

Accordingly, semiconductor region 14 includes at least one pnictide semiconductor. The term “pnictide” or “pnictide compound” refers to a molecule that includes at least one pnictogen and at least one element other than a pnictogen. The term “pnictogen” refers to any element from Group VA of the periodic table of elements. These also are referred to as Group VA or Group 15 elements. Pnictogens include nitrogen, phosphorus, arsenic, antimony, and bismuth. Phosphorus and arsenic are preferred. Phosphorus is most preferred.

In addition to the pnictogen(s), the other element(s) of a pnictide may be one or more metals, and/or nonmetals. In some embodiments, nonmetals may include one or more semiconductors. Examples of suitable metals and/or semiconductors include Si, Group IIB metals (Zn, Cd, Hg) and/or other transition metals, metals included in the lanthanoid series, Al, Ga, In, Tl, Sn, Pb, combinations of these, and the like. In addition to the semiconductor materials noted above, other examples of nonmetals include B, S, Se, Te, C, O, F, H, combinations of these, and the like. Examples of nonmetal pnictides include boron phosphide, boron nitride, boron arsenide, boron antimonide, combinations of these and the like. Pnictides that include both metal and nonmetal constituents in addition to one or more pnictogens are referred to herein as mixed pnictides. Examples of mixed pnictides are compounds that include at least one pnictogen and (a) at least one of Zn and/or Cd; and/or(b) at least one of P, As, and/or Sb.

Many embodiments of metal, non-metal, and mixed pnictides are photovoltaically active and/or display semiconductor characteristics. Examples of photovoltaically active and/or semiconducting pnictides include phosphide, nitrides, antimonides, and/or arsenides of one or more of aluminum, boron, cadmium, gallium, indium, magnesium, germanium, tin, silicon, and/or zinc. Illustrative examples of such compounds include zinc phosphide, zinc antimonide, zinc arsenide, aluminum antimonide, aluminum arsenide, aluminum phosphide, boron antimonide, boron arsenide, boron phosphide, gallium antimonide, gallium arsenide, gallium phosphide, indium antimonide, indium arsenide, indium phosphide, aluminum gallium antimonide, aluminum gallium arsenide, aluminum gallium phosphide, aluminum indium antimonide, aluminum indium arsenide, aluminum indium phosphide, indium gallium antimonide, indium gallium arsenide, indium gallium phosphide, magnesium antimonide, magnesium arsenide, magnesium phosphide, cadmium antimonide, cadmium arsenide, cadmium phosphide, combinations of these and the like.

Preferred embodiments of pnictide semiconductors comprise at least one Group IIB element and at least one Group VA element. Such materials are referred to as Group IIB/VA semiconductors. Examples of IIB elements include Zn and/or Cd. Zn is presently preferred. Examples of Group VA elements (also referred to as pnictogens) include one or more pnictogens. Phosphorous is presently preferred.

Exemplary embodiments of Group IIB/VA semiconductors include zinc phosphide (Zn₃P₂), zinc arsenide (Zn₃As₂), zinc antimonide (Zn₃Sb₂), cadmium phosphide (Cd₃P₂), cadmium arsenide (Cd₃As₂), cadmium antimonide (Cd₃Sb₂), combinations of these, and the like. In an illustrative embodiment, the Group IIB/VA semiconductor material comprises p-type and/or n-type Zn₃P₂. P-type zinc phosphide is more preferred. Group IIB/VA semiconductors may be used that include a combination of Group IIB species and/or a combination of Group VA species (e.g., CdₓZn_{y}P₂, wherein each x and y is independently about 0.001 to about 2.999 and x+y is 3). Optionally, other kinds of semiconductor materials also may be incorporated into region 14.

The pnictide compositions used in the practice of the present invention may be amorphous and/or crystalline as supplied or formed, but desirably are crystalline in the resultant device 10. Crystalline embodiments may be single crystal or polycrystalline, although single crystal embodiments are preferred. Exemplary crystalline phases may be tetragonal, cubic, monoclinic, amorphous, and the like. Tetragonal crystalline phases are more preferred, particularly for zinc phosphide.

Pnictide compositions having photovoltaic and/or semiconducting characteristics may be of n-type or p-type. P-type pnictide films are preferred for use in semiconductor region 14. Such materials may be intrinsically and/or extrinsically doped. In many embodiments, extrinsic dopants may be used in a manner effective to help establish a desired carrier density, such as a carrier density in the range from about 10¹³ cm⁻³ to about 10²⁰ cm⁻³. A wide range of extrinsic dopants may be used. Examples of extrinsic dopants include Al, Ag, B, Mg, Cu, Au, Si, Sn, Ge, Cl, Br, S, Se, Te, N, I, In, Cd, F, H, combinations of these and the like.

Semiconductor region 14 may have a wide range of thicknesses. Suitable thicknesses may depend on factors including the purpose of the region, the composition of the region, the methodology used to form the region, the crystallinity and morphology of the film(s) constituting the region, and/or the like. For photovoltaic applications, region 14 desirably has a thickness effective to capture incident light for photovoltaic performance. If the film were to be too thin, too much light may pass through the film without being absorbed. Layers that are too thick will provide photovoltaic functionality, but are wasteful in the sense of using more material than is needed for effective light capture and reduced fill factors due to increased series resistance. In many embodiments, region 14 has a thickness in the range from about 1 μm to about 100 μm, or even from about 3 μm to about 50 μm, or even from about 5 μm to about 15 μm.

Region 14 may be formed from a single layer or multiple layers. Single layers may have a generally uniform composition throughout or may have a composition that shifts throughout the film. A layer in a multilayer stack typically has a different composition than adjacent layer(s), although the composition of nonadjacent layers may be similar or different in such embodiments.

During manufacture, one or more optional treatments may be carried out on all or a portion of region 14 after the region is formed before additional layers are incorporated into device 10 or a precursor thereof. For example, optional treatments may be carried to polish the surface of region 14 prior to fabricating overlying layers, to smooth the surface, to clean the surface, to rinse the surface, to etch the surface, to reduce electronic defects, to remove oxide, to passivate, combinations of these, and the like.

For example, in one exemplary methodology, polycrystalline boules of zinc phosphide semiconductor material are grown using procedures described in the technical literature. The boules are diced into rough wafers. As an exemplary pre-pretreatment methodology, the rough wafers are polished using a suitable polishing technique. The surface quality of the wafers is further improved by an additional pre-treatment in which the wafer surfaces are subjected to at least two stages of etching and at least one oxidation that in combination not only clean the pnictide film surface, but also render the film surface highly smooth with reduced electronic defects. The surface is well-prepared for further fabrication steps. This integrated etching/oxidation/etching treatment is described in Assignee's co-pending U.S. Provisional Patent Application filed on the same date as the present application in the names of Kimball et al., titled METHOD OF MAKING PHOTOVOLTAIC DEVICES INCORPORATING IMPROVED PNICTIDE SEMICONDUCTOR FILMS, and having Attorney Docket No. Docket No 71958 (DOW0058P1), the entirety of which is incorporated herein by reference for all purposes.

As another example, a metallization/anneal/removal treatment can be formed on region 14 to dramatically improve the surface quality of pnictide films constituting all or a portion of region 14. Quality issues addressed by such a treatment include polishing damage, native oxide, adventitious carbon, other surface impurities, and the like. Quality issues such as these can lead to problems such as undue surface defect density, undue surface trap states, undue surface recombination velocity, and the like. The metallization/anneal/removal treatment is further described in Assignee's co-pending U.S. Provisional Patent Application filed on the same date as the present application in the names of Kimball et al., titled METHOD OF MAKING PHOTOVOLTAIC DEVICES INCORPORATING IMPROVED PNICTIDE SEMICONDUCTOR FILMS USING METALLIZATION/ANNEALING/REMOVAL TECHNIQUES, and having Attorney Docket No. Docket No 71956 (DOW0056P1), the entirety of which is incorporated herein by reference for all purposes. This treatment removes impurities and results in a highly passivated surface with reduced electronic defects.

Region 14 is supported upon a suitable substrate 16. Exemplary substrates 16 may be rigid or flexible, but desirably are flexible in those embodiments in which the resultant microelectronic device may be used in combination with non-flat surfaces. Substrate 16 may have a single or multilayer construction. When the pnictide film is to be incorporated into an optoelectronic device, the substrate may include at least a portion of those layers that would be underneath the film in the finished device if the device is built right side up. Alternatively, the substrate may be at least a portion of the layers that would be above the film in the finished device if the device is being fabricated in the other direction from the top down.

For purposes of illustration, substrate 14 is shown as including an optional support 18 and backside electrical contact region 20.

Support 18 may be formed from a wide range of materials. These include glass, quartz, other ceramic materials, polymers, metals, metal alloys, intermetallic compositions, woven or non-woven fabrics, natural or synthetic cellulosic materials, combinations of these, and the like. For many applications involving thin film photovoltaic devices, a conductive support such as stainless steel is preferred to enable facile contact to the back of the device. For monolithically integrated photovoltaic devices a non-conductive substrate such as polyimide is preferred. The support 18 desirably is cleaned prior to use to remove contaminants, such as organic contaminants. A wide variety of cleaning techniques may be used. As one example, plasma cleaning, such as by using RF plasma, would be suitable to remove organic contaminants from metal-containing supports. Other examples of useful cleaning techniques include ion etching, wet chemical bathing, and the like.

The backside electrical contact region 20 provides a convenient way to electrically couple the resultant device 100 to external circuitry (not shown). The backside electrical contact region 20 also helps to isolate the semiconductor region 12 from the support 18 to minimize cross-contamination. As is the case with any of the regions of device 10, region 18 may be formed from a single layer or multiple layer using a wide range of electrically conductive materials, including one or more of Cu, Mo, Ag, Au, Al, Cr, Ni, Ti, Ta, Nb, W, Zn, and combinations of these, and the like. Conductive compositions incorporating Ag may be used in an illustrative embodiment.

Generally, the backside electrical contact region 20 has a thickness effective to provide good quality ohmic contact with the semiconductor region 12 within the desired operating parameters (e.g., voltage and current specifications) of the resultant device 100. An illustrative thickness of backside electrical contact region 20 is in the range from about 0.01 to about 1 μm, preferably 0.05 to about 0.2 μm.

The backside electrical contact region 20 can be deposited on the Group IIB/VA semiconductor material after which support 18 is formed, laminated, or otherwise applied to region 18. Alternatively, the Group IIB/VA semiconductor can be deposited onto a substrate comprising a backside electrical contact region 20 and an optional support 18.

Insulating region 22 is provided on and is electrically coupled to region 14. Optionally, one or more layers (not shown) may be interposed between region 22 and region 14. For example, the metallization/anneal/removal treatment described above may tend to form a thin alloy region proximal to the treated surface of region 14. For purposes of illustration insulating region 22 is shown as being directly formed on region 14 without any intervening optional layers being shown.

A metal species is considered to be alloyable in a resultant alloy if the alloy includes at from 0.1 to 99.9 atomic percent, preferably from 1 to 99 atomic percent of that metal based on the total metal content of the alloy. Alloyable species are distinguished from dopants, which are incorporated into semiconductor films or the like at substantially lower concentrations, e.g., concentrations in the range of 1×10²⁰ cm ⁻³ to 1×10¹⁵ cm³ or even less.

Exemplary metal species that would be alloyable with pnictide film compositions include one or more of Mg, Ca, Be, Li, Cu, Na, K, Sr, Rb, Cs, Ba, Al, Ga, B, In, Sn, Cd, and combinations of these. Mg is more preferred. By way of example, Mg is alloyable with Zn₃P₂ to form a Mg₃ₓZn_{3*(1-x)}P₂ alloy in which x has a value such that the Mg content may be in the metal (or cation) atomic percent range of 0.8 to 99.2 percent based on the total amount of Mg and Zn. More preferably, x has a value in the range from 1 to 5 percent. Use of alloys with pnictide semiconductors is further described in Assignee's co-pending U.S. Provisional Patent Application filed on the same date as the present application in the names of Kimball et al., titled METHOD OF MAKING PHOTOVOLTAIC DEVICES INCORPORATING IMPROVED PNICTIDE SEMICONDUCTOR FILMS USING METALLIZATION/ANNEALING/REMOVAL TECHNIQUES, and having Attorney Docket No. Docket No 71956 (DOW0056P1), the entirety of which is incorporated herein by reference for all purposes.

In preferred embodiments, the term “insulating” with respect to region 22 means that region 22 has a resistivity and thickness such that region 22 exhibits tunnel barrier functionality between region 14 and rectifying region 24. Region 22 may have a wide range of thicknesses. If region 22 is too thick, however, the resistance may be too high, reducing the tunnel barrier properties and thereby degrading electrical performance. If the layer is too thin, the passivation effects and ability to serve as a tunnel barrier may be reduced more than desired. Balancing such concerns, illustrative embodiments of region 22 desirably has a thickness in the range from 0.5 nm to 20 nm, preferably 1 nm to 15 nm, more preferably 1 nm to 10 nm. These thicknesses are about an order of magnitude less than the thickness of layers of similar materials serving as a heterojunction partner, but the atypically thin layers nonetheless function as excellent tunnel barriers in MIS and SIS structures. Resisitivity of region 22 also may be within a wide range. In many embodiments, region 22 has a resistivity that is greater than the resistivity of either regions 14 or 24 and is at least 10⁻¹ ohm-cm or greater, preferably at least 10³ ohm-cm or greater, more preferably at least 10⁵ ohm-cm or greater, or even at least 10⁷ ohm-cm or greater. In many embodiments, the resistivity of region 22 is less than 10¹² ohm-cm or even less than 10¹⁰ ohm-cm.

Insulating region 22 comprises at least one chalcogenide compound. The term “chalcogenide” or “chalcogenide compound” refers to a molecule that includes at least one chalcogen and at least one element other than a chalcogen. The term “chalcogen” refers to any element from Group 16 of the periodic table of elements. Chalcogens include O, S, Se, and/or Te. Preferred chalcogenides are sulfides, selenides, tellurides, or compounds containing two or more of O, S, Se, and/or Te. Chalcogenide compositions suitable for use in region 22 may be of i-type, n-type or p-type. If n-type or p-type, the n- or p- character often is generally weak such that the resistivity of the material is still relatively high so that the material functions as in insulating material. More preferably, i-type chalcogenide films such as i-ZnS, are preferred for use in region 22. An i-type chalcogenide film is a film that is intrinsically doped.

In addition to the chalcogen(s), the other element(s) of a chalcogenide may be one or more metals, and/or nonmetals. In some embodiments, nonmetals may include one or more semiconductors. Examples of suitable metals and/or semiconductors include Si, Examples of suitable metals and/or semiconductors include Si, Ge, Group IIB metals (Zn, Cd, Hg), Al, Ga, In, Tl, Sn, Pb , other transition metals, metals included in the lanthanoid series, combinations of these, and the like. In addition to the semiconductor materials noted above, other examples of nonmetals include B, S, Se, Te, C, O, F, H, combinations of these, and the like. Examples of nonmetal chalcogenides include boron sulfide, boron selenide, boron sulfide selenide, combinations of these and the like. Chalcogenides that include both metal and nonmetal constituents in addition to one or more chalcogens are referred to herein as mixed chalcogenides.

Chalcogenide compositions also desirably have a band gap that is greater than the band gap of the semiconductor region 14. In some modes of practice the ratio of the band gap of a suitable chalcogenide composition to the band gap of region 14 desirably is 1.2:1 or more, ore even 2:1 or more, or even 3:1 or more. In illustrative embodiments, a chalcogenide composition has a band gap of at least 2.2 eV, preferably at least 3.2 eV, or even at least 5 eV. By way of example, i-ZnS has a band gap of 3.68 eV.

In preferred embodiments, a chalcogenide used in region 22 includes one or more Group II metals and one or more Group VI chalcogens. Group II metals are metals including two electrons in their outer electron shells. These include Zn, Mg, Be, Ca, Sr, Ba, Ra, Cd, and/or Hg. ZnS, ZnSe, or zinc sulfide selenide are preferred chalcogenides of this type. ZnS is more preferred. In preferred embodiments, insulating region 22 comprises zinc-containing chalcogenides such as zinc sulfide, zinc selenide, zinc sulfide selenide, zinc telluride, zinc sulfide telluride, zinc selenide telluride, and zinc sulfide, selenide telluride. Zinc sulfide is preferred, particularly when the semiconductor region 14 includes zinc phosphide. Advantageously, zinc sulfide has a type I band alignment with a conduction band offset and valence band offset of 1 eV and 1.2 eV, respectively. These offsets were determined using high resolution X-ray photoelectron spectroscopy according to the Kraut method described in Kraut et al., Phys. Rev. Lett. 44, 1620 (1980); and Kraut et al., Phys. Rev. B 28, 1965 (1983).

Chalcogenide alloys also may be used in region 22. Alloys may be desirable in some embodiments in order to tune band alignment, lattice matching, or the like. Alloys include ternary and quaternary alloys. Exemplary alloys are one or more of M₁₋ₓZnₓS, ZnS_{1-y}Se, MₓZn₁₋ₓS_{1-y}Se_{y}, wherein each M independently is another metal other than Zn, each x and y independently is in the range from preferably 0.001 to 0.999. In some instances, incorporating too much M into an alloy can unduly reduce desired characteristics such as stability. For instance, alloys including more than about 60 atomic percent Mg relative to the total amount of Mg and Zn might have poorer stability in air than is desired. Accordingly, in such embodiments, the content of Mg is limited to avoid undue stability reduction. This corresponds to x values in the range from 0.4 to 0.999.

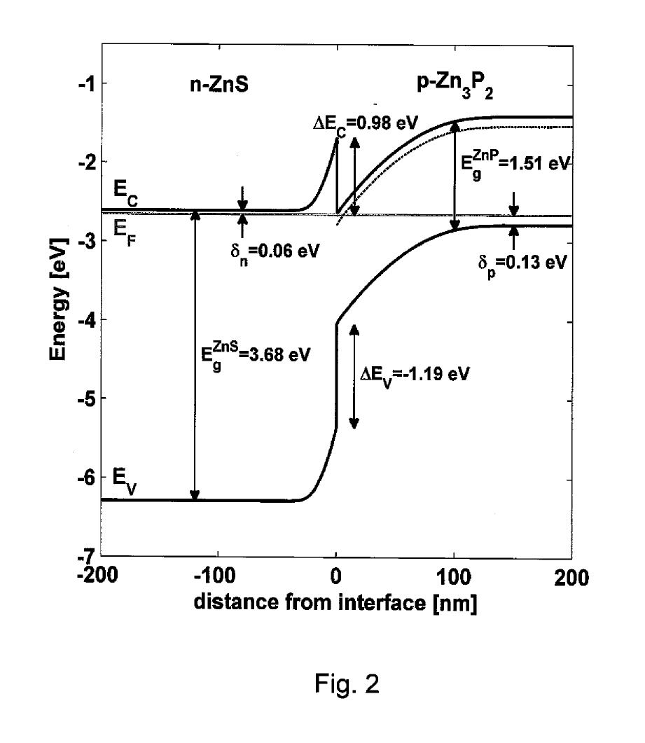

FIG. 2 illustrates a possible band alignment for an n-ZnS/Zn₃P₂ interface. The n-ZnS is used directly as a p-n heterojunction partner with the zinc phosphide. FIG. 2 shows band alignment of a proposed n-ZnS/p-Zn3P2 heterojunction solar cell as experimentally determined by EPS measurements. FIG. 2 shows a large conduction band spike for this heterojunction interface. This indicates a poor quality heterojunction because carrier transport across the interface would be inhibited. Advantageously, however, the present invention appreciates that the interface, although unsuitable for use as a heterojunction in a p-n device, nonetheless would be an excellent tunnel barrier in MIS or SIS devices incorporating such an interface due at least in part to the Type I band alignment. Accordingly, at least a portion of an aspect of the present invention is to appreciate that chalcogenides with a Type I band alignment with a pnictide semiconductor can form a tunnel barrier (i.e., the I layer) in MIS and SIS devices in which at least one of the S layers includes at least one pnictide semiconductor.

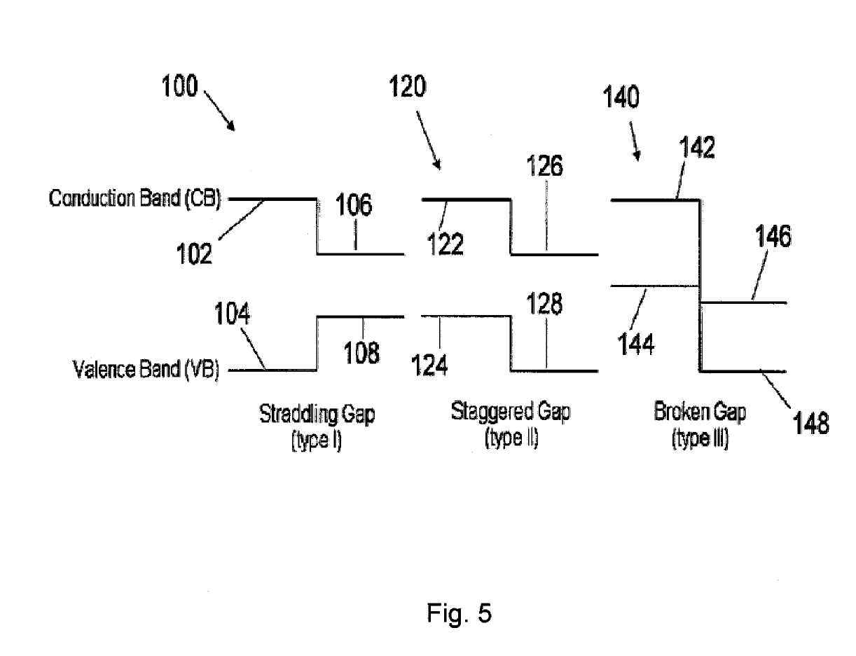

A p-n heterojunction typically is formed between a material with a higher band gap and a second material with a smaller band gap, wherein the band gap is the gap between the conduction band and valence band of each material. The band gaps between the two materials can align in different ways. FIG. 5 shows Type I alignment 100, Type II alignment 120, and Type III alignment 140. Type I band alignment refers to an alignment that occurs in the p-n heterojunction where the conduction band and valence band edges of the smaller bandgap material reside entirely within the conduction and valence band edges of the larger bandgap material. In Type I alignment 100, the larger band gap material has conduction band and valence band 102 and 104 respectively. The smaller band gap material has conduction band and valence band 106 and 108, respectively. Note that bands 106 and 108 are entirely between bands 102 and 104 to provide the Type I alignment, also referred to as a straddling gap alignment.

Type II alignment 120 shows conduction and valence bands 122 and 124, respectively for the large band gap material and conduction and valence bands 126 and 128 for the smaller band gap material. The band gap between bands 126 and 128 overlaps the band gap between bands 122 and 124. A Type II alignment is also referred to as a staggered gap alignment.

Type III alignment 140 shows conduction and valence bands 142 and 144, respectively for the large band gap material and conduction and valence bands 146 and 148 for the smaller band gap material. The band gap between bands 146 and 148 is below and has no overlap with the band gap between bands 142 and 144. A Type III alignment is also referred to as a broken gap alignment.

Without wishing to be bound by theory, it is believed that tunnel barrier functionality arises at least in part due to an ability of the ZnS to passivate the Zn₃P₂ and/or the interface between the ZnS and the Zn₃P₂. This is suggested by experimental reports showing that ZnS passivates heterojunction interfaces in applications in which ZnS is a more suitable p-n heterojunction partner with Si, Cu(In,Ga)Se₂, CdTe, and GaAs. G. A. Landis, J. J. Loferski, R. Beaulieu, P. A. Sekulamoise, S. M. Vernon, M. B. Spitzer, and C. J. Keavney, IEEE Trans. Elect. Dev. 37, 372 (1990); Y. H. Kim, S. Y. An, J. Y. Lee, I. Kim, K. N. Oh, S. U. Kim, M. J. Park, and T. S. Lee, J. Appl. Phys. 85, 7370 (1999); T. Nakada, M. Mizutani, Y. Hagiwara, and A. Kunioka, Sol. Energy Mater. Sol. Cells 67, 255 (2001); J. M. Woodall, G. D. Pettit, T. Chappell, and H. J. Hovel, J. Vac. Sci. Technol. 16, 1389 (1979).

The principles of the present invention can be used, therefore, to identify partners for MIS and SIS junctions in photovoltaic devices via the band alignment between candidate materials. The degree to which band alignment corresponds to a Type I alignment is indicative of tunnel barrier performance. Generally, an increasing degree by which the observed alignment approaches or achieves Type I alignment indicates better tunnel barrier properties. Additionally, without wishing to be bound by theory, it is also believed that Type I alignment provides, better passivation due to improved electronic characteristics. In short, the degree to which band alignment corresponds to a Type I alignment is indicative of greater suitability for use in MIS and SIS devices.

The chalcogenide compositions used in the practice of the present invention may be amorphous and/or crystalline as supplied or formed, but desirably are crystalline in the resultant device 10. Crystalline embodiments may be single crystal or polycrystalline, although single crystal embodiments are preferred. Exemplary crystalline phases may be zinc blende, Wurtzite, tetragonal, cubic, monoclinic, and the like.

The chalcogenide materials used in region 22 may be intrinsically and/or extrinsically doped. A material such as i-ZnS, for instance, may be used in SIS and MIS structures to enhance both the barrier height of the devices as well as to reduce parasitic losses in current due to factors such as reflection and absorption. In many embodiments, extrinsic dopants may be used in a manner effective to help establish a desired carrier density, such as a carrier density in the range from about 10¹³ cm³ to about 10²⁰ cm ³. A wide range of extrinsic dopants may be used. Examples of extrinsic dopants include B, Al, Ga, In, F, Cl, Br, I, Mn, Cu, Ag, Li, Na, K and combinations of these and the like. Region 22 may be formed from a single layer or multiple layers. Single layers may have a generally uniform composition throughout or may have a composition that shifts throughout the film. A layer in a multilayer stack typically has a different composition than adjacent layer(s), although the composition of nonadjacent layers may be the similar or different in such embodiments.

Device 10 incorporates rectifying region 24. In the context of a photovoltaic device, a rectifying region refers to a region that is in rectifying electrical communication with the semiconductor region 14. Generally, “rectifying” means that the I-V characteristics of the junction formed by rectifying region 24, insulator region 22, and semiconductor region 14 are non-linear and asymmetric. Rectifying region 24 is electrically coupled to semiconductor region 14 such that insulating region 22 is electrically interposed between rectifying region 24 and semiconductor region 14. If the rectifying region 24 includes a semiconductor, device 10 has an SIS structure. If rectifying region 24 comprises one or more metals, device 10 has an MIS structure.

Without wishing to be bound by theory, it is believed that the rectifying region 24 also is a region in which the majority carriers are of the same type as the minority carriers of the semiconductor region 14. Under this theory, a rectifying region “collects” minority carriers from the semiconductor region 14 and “converts” them into majority carriers. In some instances, therefore, rectifying regions such as region 24 are referred to in the industry as “collectors.”

In MIS embodiments of device 10, a wide range of one or more metals may be incorporated into region 24. Generally, the term metals includes metals, metal alloys, intermetallic compositions, and/or the like. Suitable metals are those that, if region 22 were absent, would form a rectifying, non-ohmic electrical contact (also referred to as a Schottky contact) if deposited in direct contact with region 14. Exemplary metals include Mg, Be, Ca, Sr, Ba, Al, Ga, In, Hg, combinations of these, and the like. Particular metal(s) may be selected to increase the barrier height of the MIS device, and thereby potentially increase the open-circuit voltage, and hence the photovoltaic conversion efficiency, as well. Mg metal is preferred due to its low work function value of 3.8 eV. Mg provides excellent performance in MIS structures, particularly in combination with i-ZnS in the I layer and Zn₃P₂ in the S layer.

Preferred collector regions 24 in SIS devices have a wider band gap than the semiconductor region 14. Desirably, the ratio of the band gap of rectifying region 24 to semiconductor region 14 is at least 1.1:1, preferably at least 1.5:1, more preferably at least 2:1. By way of example, n-ZnS has a band gap of 3.68 eV, making n-ZnS a suitable collector in an SIS structure with zinc phosphide (band gap of 1.5 eV) as the semiconductor region 14.

A wide variety of semiconductor materials may be used in region 24 in SIS embodiments of device 10. These include semiconductors based on Si, Ge, pnictides, chalcogenides, mgCdS, MgCdSe, combinations of these, and the like. More preferred semiconductor materials for use in region 24 have a higher barrier height with respect to region 14. A barrier height difference of at least 1.2 eV is desired.

In some SIS embodiments, one or more semiconductor chalcogenides are included in region 24. These include one or more Group II elements and one or more Group VI elements. Group II elements include at least one of Cd and/or Zn. Zn is preferred. The Group VI materials, also referred to as chalcogens, include O, S, Se, and/or Te. S and/or Se are preferred. S is more preferred in some embodiments. A combination of S and Se is more preferred in other representative embodiments, wherein the atomic ratio of S to Se is in the range from 1:100 to 100:1, preferably 1:10 to 10:1, more preferably 1:4 to 4:1. In one particularly preferred embodiment, using 30 to 40 atomic percent S based on the total amount of S and Se would be suitable. The emitter materials that incorporate one or more chalcogens also may be referred to as chalcogenides herein. Exemplary semiconductor chalcogenides include ZnS, ZnSe, ZnTe, ZnS_{1-y}Se_{y}, Zn₁₋ₓCdₓSe, ZnS_{1-y}O_{y}, CdS, Zn₁₋ₓCdₓS, Mg₁₋ₓZnₓS, combinations of these, and the like. In these formulae, x and y are as defined above.

A particularly preferred Group II/Group VI semiconductor comprises zinc sulfide. Some embodiments of zinc sulfide may have a sphalerite or wurtzite crystalline structure. Intrinsically, the cubic form of zinc sulfide has a band gap of 3.68 eV at 25° C. whereas the hexagonal form has a band gap of 3.91 eV at 25° C. In other embodiments, zinc selenide may be used. Zinc selenide is an intrinsic semiconductor with a band gap of about 2.70 eV at 25° C.

Zinc sulfide selenide semiconductors also may be used. Illustrative embodiments of zinc sulfide selenide may have the composition ZnS_{y}Se_{1-y}, where y has a value such that the atomic ratio of S to Se is in the range from 1:100 to 100:1, preferably 1:10 to 10:1, more preferably 1:4 to 4:1. In one particularly preferred embodiment, using 30 to 40 atomic percent S based on the total amount of S and Se would be suitable.

Advantageously, ZnS, ZnSe, or zinc sulfide selenide materials offer the potential to optimize several device parameters, including conduction band offset, band gap, surface passivation, and the like. These materials also may be grown from compound sources as taught in co-pending U.S. Provisional Patent Application Ser. No. 61/441,997, filed Feb. 11, 2011, in the names of Kimball et al. titled Methodology For Forming Pnictide Compositions Suitable For Use In Microelectronic Devices and having Docket No 70360 (DOW0039P1), which is advantageous for many reasons including facilitating manufacture on industrial scales. However, while these zinc chalcogenides are very good matches for pnictide semiconductors such as zinc phosphide, the magnitude of the conduction band offset between the two kinds of materials can still be unduly high. The lattice mismatch may be greater than desired. For instance, ZnS and Zn₃P₂ have a conduction band offset of 1.0 eV, which is still large enough to cause undue loss in electrical current in some modes of practice. There can also be a lattice mismatch (about 5.5%) between the two materials.

When region 24 includes one or more semiconductor chalcogenides, techniques optionally may be used to reduce the conduction band offset and improve the lattice match between the absorber and the collector. Tuning techniques are described in Assignee's co-pending U.S. Provisional Patent Application in the names of Bosco et al., titled METHOD OF MAKING PHOTOVOLTAIC DEVICES WITH REDUCED CONDUCTION BAND OFFSET BETWEEN PNICTIDE ABSORBER FILMS AND EMITTER FILMS., and having Attorney Docket No. Docket No 71957 (DOW0057P1), the entirety of which is incorporated herein by reference for all purposes.

Optionally, region 24 may include one or more additional constituents. Examples of such constituents include dopants to enhance n-type or p-type characteristics and/or to increase the bandgap of region 24. Exemplary dopants that may be included in region 24 include Al, Cd, Sn, In, Ga, F, combinations of these, and the like. Aluminum doped embodiments of chalcogenide semiconductors are described in Olsen et al., Vacuum-evaporated conducting ZnS films, Appl. Phys. Lett. 34(8), 15 Apr. 1979, 528-529; Yasuda et. al., Low Resistivity Al-doped ZnS Grown by MOVPE, J. of Crystal Growth 77 (1986) 485-489. Tin doped embodiments of chalcogenide semiconductors are described in Li et al, Dual-donor codoping approach to realize low-resistance n-type ZnS semiconductor, Appl. Phys. Lett. 99(5), August 2011, 052109.

Region 24 may have a wide range of thicknesses. Suitable thicknesses may depend on factors including the purpose of the film, the composition of the film, the methodology used to form the film, the crystallinity and morphology of the film, and/or the like. For photovoltaic applications, if region 24 were to be too thin, then the device 10 may be shorted or the depletion region at the junction interface(s) could unduly encompass region 24. Layers that are too thick might result in excessive free-carrier recombination, hurting the device current and voltage and ultimately decreasing device performance. In many embodiments, balancing these concerns, many embodiments of region 24 have a thickness in the range from about 10 nm to about 1 microns, or even from about 50 nm to about 200 nm. Antireflection properties of the layer may also further constrain the layer thickness.

Additional layers complete device 10. Window layer 26 is provided over the region 24. Transparent electrode layer 28 is formed over window layer 26. Collection grid 30 is formed over layer 28. One or more environmental protection barriers represented schematically by layer 32 can be used to protect device 10 from the ambient.

In a particularly preferred embodiment corresponding to device 10, semiconductor region 14 comprises zinc phosphide, insulating region 22 comprises i-ZnS, and rectifying region 24 comprises Mg. The three layers thus provide an MIS structure.

The components and features of device 10 may be fabricated using a wide range of techniques. Exemplary techniques include congruent sublimation from compound sources as described in Assignee's co-pending U.S. Provisional Patent Application Ser. No. 61/441,997, titled METHODOLOGY FOR FORMING PNICTIDE COMPOSITIONS SUITABLE FOR USE IN MICROELECTRONIC DEVICES, having attorney docket No. 70360-US-PSP (DOW0039/P1), filed Feb. 11, 2011, in the names of G. M. Kimball et al., the entirety of which is incorporated herein by reference for all purposes, chemical vapor deposition (CVD) such as metal organic chemical vapor deposition, chemical bath deposition, evaporation, plating, annealing, atmospheric pressure CVD, low pressure CVD, ultrahigh vacuum CVD, aerosol assisted CVD, plasma assisted CVD, rapid thermal CVD, molecular beam epitaxy, liquid bath epitaxy, vapor phase epitaxy, ion beam sputtering, reactive sputtering; DC magnetron sputtering, ion-assisted deposition, RF sputtering, high target utilization sputtering, crystal growing strategies, gas flow sputtering plasma enhanced deposition, atomic layer deposition, combinations of these, and the like.

The present invention will now be further described with reference to following illustrative examples.

### EXAMPLES

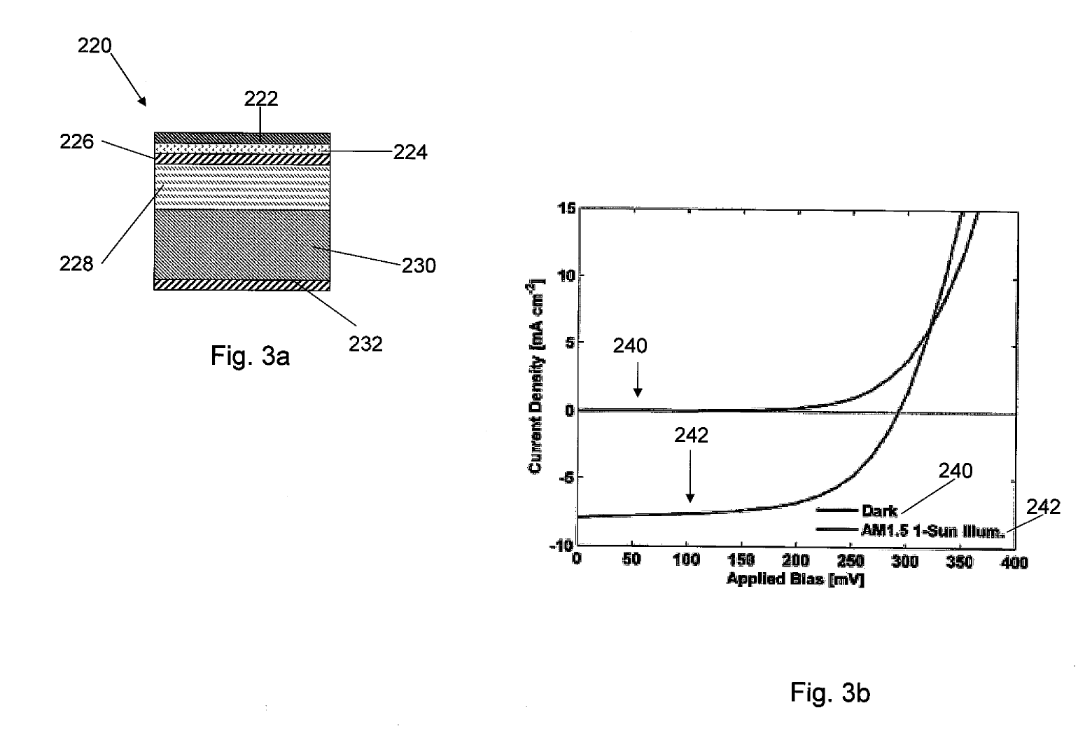

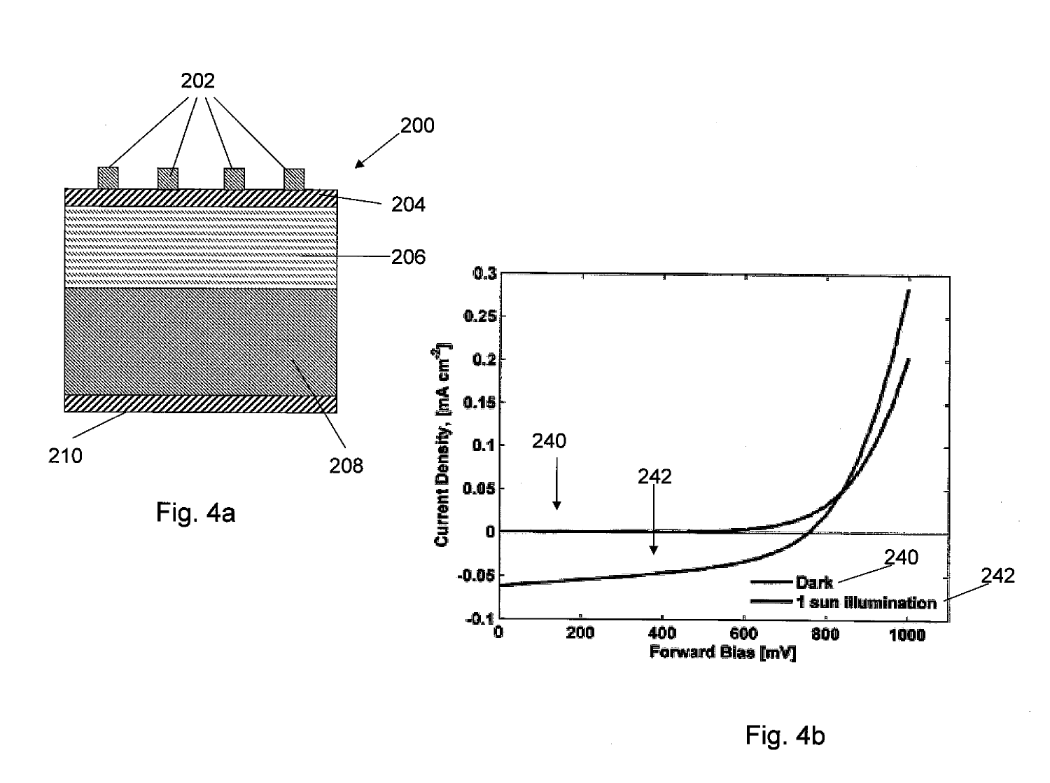

Solar cells having a Mg/i-ZnS/p-Zn₃P₂ structure (MIS-type solar cell, shown in FIG. 3a) as well as a control n-ZnS:Al/p-Zn₃P₂ heterojunction solar cell (FIG. 4a) are prepared, respectively, on p⁺-GaAs substrates using the apparatus, compound sources, and congruent sublimation techniques. FIG. 4a shows a solar cell 200 with Pt/Ti/Pt back contact 210, p⁺-GaAs substrate 208, p-Zn₃P₂ (1 μm) 206, n⁺-ZnS (120 nm) 204, and Al top contact 202. The fabrication equipment is also configured with additional source capability for addition of extrinsic dopants during growth. Deposition of Zn₃P₂, ZnS, and Mg films was performed in an ultra-high vacuum MBE chamber that had an ultimate pressure of <2×10⁻¹⁰ Torr. The Zn₃P₂ source material was synthesized from elemental zinc and phosphorus (99.9999%, Alfa Aesar) at 850° C. [A. Catalano, J. Cryst. Growth, 49 (1980) 681-686. F. C. Wang, A. L. Fahrenbruch, R. H. Bube, J. Electron. Mater., 11 (1982) 75-88. S. Fuke, Y. Takatsuka, K. Kuwahara, T. Imai, J. Cryst. Growth, 87 (1988) 567-570]. Commercially available zinc sulfide (99.9999%) and Mg metal (99.9999%) were also used. Standard Knudsen effusion cells were used to provide sublimation sources for all three materials. Zinc-doped, p⁺-GaAs(001) single crystal wafers (AXT) were used as epitaxial substrates. A Pt/Ti/Pt ohmic back contact was deposited onto the GaAs substrate prior to cell fabrication. The GaAs was then mounted to a Mo chuck using an In—Ga eutectic. The substrate was degassed at 350° C. for 1 h in vacuum, and the native oxide was removed by exposure at 450° C. to an atomic hydrogen flux for ˜5 min [C. Rouleau, R. Park, J. Appl. Phys., 73 (1993) 4610-4613.]. The removal of the native oxide was verified in situ using RHEED, which yielded a streaky (1×1) surface reconstruction.

Following GaAs substrate surface preparation, the MIS cells of FIG. 3a were fabricated by depositing a thick layer of Zn₃P₂ (1˜5 μm) followed by a thin (1˜3 nm) layer of intrinsic ZnS, and then ˜10 nm of Mg metal. The Zn₃P₂ and ZnS films were deposited at a substrate temperature of 200° whereas the Mg metal film was deposited at 100° C. FIG. 3a shows a cell 220 with Pt/Ti/Pt back contact 232, p⁺-GaAs substrate 230, p-Zn₃P₂ (1 μm) 228, i-ZnS (1˜2 nm) 226, Mg metal (˜10 nm) 224, and ITO contact (˜70 nm) 222. Finally, a top conductive layer of indium tin oxide (ITO) was deposited on top of the device by sputtering through a 1 mm×1 mm physical mask. The ITO top contact also provided device isolation.

For the heterojunction solar cell shown in FIG. 4a, following deposition of the thick Zn₃P₂ layer, a 120 nm ZnS layer was deposited. The ZnS was n-type doped with extrinsic Al metal impurities using an additional evaporation source. An Al metal busbar was used to make a top contact to the doped ZnS emitter film.

Current-voltage (IV) characterization of the solar cell devices was performed under dark 240 and AM1.5 1-sun illumination 242 conditions. IV measurements for the MIS device are displayed in FIG. 3b. FIG. 3b illustrates the current-voltage measurement under dark and AM1.5 1-Sun illumination for Mg/i-ZnS/p-Zn3P2 MIS photovoltaic device of FIG. 3a. The MIS device showed photovoltaic conversion efficiencies of 1.3˜1.5%, with open circuit voltages of ˜300 mV, short circuit current densities of 7˜8 mA cm⁻² and fill factors exceeding 55%.

IV measurements for the ZnS/Zn₃P₂ device are displayed in FIG. 4b. FIG. 4b illustrates current-voltage measurement under dark 240 and AM1.5 1-Sun illumination 242 for the n-ZnS/p-Zn3P2 heterojunction photovoltaic device of FIG. 4a. The ZnS/Zn₃P₂ heterojunction control devices showed less than 0.1% photovoltaic conversion efficiency due to the inability to pass sufficient current through the devices. This is due to the large conduction band spike at the ZnS/Zn₃P₂ interface mentioned earlier. These devices did however demonstrate open-circuit voltages of greater than 700 mV, which is higher than values reported previously, indicating improved passivation of the Zn₃P₂ surface.

These results show that the band alignment between ZnS/Zn₃P₂ is such that the ZnS provides passivation of the Zn₃P₂ surface and performs well as a tunnel barrier (intrinsic layer) in an MIS solar cell device incorporating Zn₃P₂ as the photovoltaic absorber.

1. A photovoltaic device, comprising:
a) a semiconductor region comprising at least one pnictide semiconductor;
b) an insulating region electrically coupled to the semiconductor region, wherein the insulating region comprises at least one chalcogenide, at least one Group II metal, and has a thickness in the range from 0.5 nm to 20 nm; and
c) a rectifying region in rectifying electrical communication with the semiconductor region in a manner such that the insulating region is electrically interposed between the rectifying region and the semiconductor region.

2. A method of making a photovoltaic device, comprising the steps of:
a) providing a semiconductor layer comprising at least one pnictide semiconductor;
b) forming an insulating layer directly or indirectly on the semiconductor layer, wherein the insulating layer comprises at least one chalcogenide, at least one Group II metal, and has a thickness in the range from 0.5 nm to 20 nm; and
c) forming an additional layer directly or indirectly on the insulating layer such that the insulating layer is electrically interposed between the additional layer and the semiconductor layer and such that the semiconductor layer, the insulating layer, and the additional layer form a photovoltaic junction in which the additional layer is in rectifying electrical communication with the semiconductor layer.

3. The device of claim 1, wherein the pnictide semiconductor comprises zinc and phosphorous.

4. The device of claim 1, wherein the chalcogenide comprises zinc and sulfur or i-ZnS.

5. The device of claim 1 wherein the pnictide semiconductor and the chalcogenide have a Type I band alignment.

6. The method of claim 2, wherein the photovoltaic junction comprises an MIS or SIS junction.

7. The device of claim 1, wherein the insulating layer has a thickness in the range from 1 nm to 15 nm.

8. The device of claim 1, wherein the insulating layer has a thickness in the range from 1 nm to 10 nm.

9. The device of claim 1, wherein the insulating layer comprises at least one zinc-containing chalcogenide.

10. The device of claim 1, wherein the insulating layer comprises at least one zinc-containing chalcogenide selected from the group consisting of ZnSe, ZnTe, ZnS_{1-y}Se_{y}, ZnS_{1-y}O_{y}, CdS, Zn₁₋ₓCdₓS, Mg₁₋ₓZnₓS, and combinations of these.

11. The device of claim 1, wherein the semiconductor region comprises a semiconductor selected from zinc arsenide (Zn₃As₂), zinc antimonide (Zn₃Sb₂), cadmium phosphide (Cd₃P₂), cadmium arsenide (Cd₃As₂), cadmium antimonide (Cd₃Sb₂), and combinations of these.

12. The device of claim 1, wherein the semiconductor region comprises p-type zinc phosphide.

13. The device of claim 1, wherein the semiconductor region comprises p-type zinc phosphide, said semiconductor region comprising a pnictide alloy proximal to an interface between the semiconductor region and the insulating region.

14. The device of claim 1, wherein the rectifying region is a metal conductor comprising Mg.

15. The device of claim 1, wherein the rectifying region comprises a semiconductor selected from ZnS, ZnSe, ZnTe, ZnS_{1-y}Se_{y}, Zn₁₋ₓCdₓSe, ZnS_{1-y}O_{y}, CdS, Zn₁₋ₓCdₓS, Mg₁₋ₓZnₓS, and combinations of these.
